(19) United States
(12) Patent Application Publication
(10) Pub. No.: US 2019/0281820 A1
(43) Pub. Date: Sep. 19, 2019

(54) ANTIBACTERIAL FIBER

(71) Applicant: Murata Manufacturing Co., Ltd., Nagaokakyo-shi (JP)

(72) Inventors: Kentaro USUI, Nagaokakyo-shi (JP); Takashi KIHARA, Nagaokakyo-shi (JP); Yoshihiro YAMAGUCHI, Nagaokakyo-shi (JP); Shozo OTERA, Nagaokakyo-shi (JP); Fumiya ISONO, Nagaokakyo-shi (JP); Masamichi ANDO, Nagaokakyo-shi (JP); Yutaka ISHIURA, Nagaokakyo-shi (JP)

(21) Appl. No.: 16/434,407

(22) Filed: Jun. 7, 2019

Related U.S. Application Data
(63) Continuation of application No. PCT/JP2017/045056, filed on Dec. 15, 2017.

(30) Foreign Application Priority Data
Dec. 20, 2016 (JP) 2016-246747

(51) Int. Cl. A01N 25/10; D02G 3/36; D02G 3/38; H01L 41/193; A01N 37/02; A01N 29/02

(52) U.S. Cl. CPC A01N 25/10; D02G 3/36; D02G 3/38; H01L 41/193; A01N 37/02; D10B 2321/042; D10B 2401/13; D10B 2401/16; D10B 2401/06; D10B 2331/041; A01N 29/02

(57) ABSTRACT

An antibacterial fiber that includes a charge generation member shaped in a fibrous form and that generates charges sufficient to suppress the proliferation of a bacillus by input of external energy, and a water-resistant member that covers the charge generation member.

### CROSS REFERENCE TO RELATED APPLICATIONS

The present application is a continuation of International application No. PCT/JP2017/045056, filed Dec. 15, 2017, which claims priority to Japanese Patent Application No. 2016-246747, filed Dec. 20, 2016, the entire contents of each of which are incorporated herein by reference.

### FIELD OF THE INVENTION

The present invention relates to an antibacterial fiber with antibacterial properties.

### BACKGROUND OF THE INVENTION

Conventionally, many proposals have been made on fiber materials with antibacterial properties (see Patent Documents 1 to 7).

Patent Document 1: Japanese Patent No. 3281640

Patent Document 2: Japanese Patent Application Laid-Open No. 7-310284

Patent Document 3: Japanese Patent No. 3165992

Patent Document 4: Japanese Patent No. 1805853

Patent Document 5: Japanese Patent Application Laid-Open No. 8-226078

Patent Document 6: Japanese Patent Application Laid-Open No. 9-194304

Patent Document 7: Japanese Patent Application Laid-Open No. 2004-300650

### SUMMARY OF THE INVENTION

However, all the materials with antibacterial properties have failed to provide long lasting effects.

Further, the materials with antibacterial properties may cause an allergic reaction due to drugs or the like.

Therefore, an object of the present invention is to provide an antibacterial fiber which has a longer lasting effect than conventional materials with antibacterial properties, and which is safer than drugs and the like.

The antibacterial fiber of the present invention includes a charge generation member shaped in a fibrous form and that generates charges sufficient to suppress the proliferation of a bacillus by input of external energy, and a water-resistant member that covers the charge generation member.

Conventionally, it has been known that the proliferation of bacteria or fungi can be inhibited by an electric field (see, for example, Tetsuaki Doito, Hiroshi Koryo, Hideaki Matsuoka, Junichi Koizumi, Kodansha: Microbial Control-Science and Engineering; see for example, Koichi Takagi, Application of High Voltage Plasma Technology to Agriculture Food Field, and see J. HTSJ, Vol. 51, No. 216). A potential which produces the electric field may cause an electric current to flow in a current path formed due to humidity or the like, or in a circuit formed through a local phenomenon of microdischarge.

This electric current is considered to weaken bacteria and inhibit the proliferation of bacteria. The charge generation yarn for bacterium-countermeasure of the present invention includes a plurality of charge generation fibers that generate charges by external energy, and thus generates an electric field when the antibacterial fiber is brought between yarns or close to an object with a prescribed electric potential (including a ground potential), such as a human body. Alternatively, the charge generation yarn for bacterium-countermeasure of the present invention allows an electric current to flow when is brought between yarns or close to an object with a prescribed electric potential (including a ground potential), such as a human body, with moisture such as sweat interposed therebetween.

Therefore, the charge generation yarn for bacterium-countermeasure of the present invention exerts an antibacterial effect (an effect of suppressing generation of bacteria) or a sterilizing effect (an effect of killing bacteria) for the following reasons. The direct action of an electric field or an electric current that is generated when the antibacterial fiber is applied to an object (a clothing article, footwear, or a medical supply such as a mask) for use close to an object with a prescribed potential, such as a human body, poses a problem for cell membranes of bacteria or an electron transfer system for maintaining the lives of bacteria, thereby killing the bacteria, or weakening the bacteria themselves. Furthermore, oxygen included in water may be changed to active oxygen species by an electric field or an electric current, or oxygen radicals may be generated in cells of bacterium due to the stress environment in the presence of an electric field or an electric current, and the action of the active oxygen species including radicals kills or weakens bacteria. In addition, the above-mentioned reasons may be combined to produce an antibacterial effect and a sterilizing effect in some cases.

Further, the antibacterial fiber of the present invention includes a water-resistant member that covers the charge generation fiber. Antibacterial fibers may be used, for example, for clothing articles. Clothing articles often allow stains (for example, rain stains) to adhere thereto and often come in contact with water for washing. Since the antibacterial fiber of the present invention includes a water-resistant member that covers a charge generation fiber, the antibacterial fiber can prevent adhesion of stains and can improve resistance to water at the time of washing.

The charge generation fiber that generates charges with external energy is considered as, for example, a material that has a photoelectric effect, a material that has a pyroelectric effect, or a fiber that uses a piezoelectric body or the like. In addition, a configuration in which a conductor is used as a core yarn, an insulator is wound around the conductor, and an electricity is applied to the conductor to generate charges also serves as a charge generation fiber.

When a piezoelectric body is used, an electric field is generated by piezoelectricity, and thus, no power supply is required, and there is no risk of electric shock. In addition, the lifetime of the piezoelectric body lasts longer than the antibacterial effect of a drug or the like. In addition, the piezoelectric body is less likely to cause an allergic reaction than drugs.

According to the present invention, an antibacterial fiber can be achieved which has a longer lasting effect than conventional materials with antibacterial properties, and which is safer than drugs and the like.

### BRIEF EXPLANATION OF THE DRAWINGS

FIG. 1(A) is a view illustrating the configuration of a piezoelectric yarn 1, FIG. 1(B) is a plan view of a piezoelectric film 10, and FIG. 1(C) is a cross-sectional view of the piezoelectric film 10.

FIG. 2(A) and FIG. 2(B) are views illustrating a relationship of a uniaxially stretching direction of polylactic acid, an electric field direction, and deformation of a piezoelectric film 10.

FIG. 3 is a view illustrating a piezoelectric yarn 1 to which external force is applied.

FIG. 4 is a view illustrating the configuration of a piezoelectric yarn 2.

FIG. 5(A) is a schematic plan view of a cloth 100 and FIG. 5(B) is a view illustrating the arrangement of individual yarns.

FIG. 6 is a view illustrating electric fields generated between individual yarns.

FIG. 7(A) is a view illustrating a covering yarn 1A formed by twisting a piezoelectric fiber 10A having a circular cross section and FIG. 7(B) is a cross-sectional view of the piezoelectric fiber 10A.

FIG. 8 is a view illustrating the configuration of a more elasticized antibacterial fiber 1B.

FIG. 9 is a view illustrating a covering yarn 1C formed by twisting a piezoelectric fiber 10A having a circular cross section and an elastic body 110.

FIG. 10(A) is a schematic plan view of a cloth 100A and FIG. 10(B) is a view illustrating electric fields generated between individual yarns.

FIG. 11(A) is a view illustrating the configuration of a cloth 100B made of a knitted fabric and FIG. 11(B) is a view illustrating a cloth 100C in which a knitted fabric is constituted by knitting piezoelectric yarns 1, piezoelectric yarns 2 and conductive yarns 5.

FIG. 12 is a view illustrating the configuration of a cloth 100D having both air permeability and heat retention.

FIG. 13(A) is a view illustrating the polarity of electric charges generated in piezoelectric yarns 1 and piezoelectric yarns 2 and FIG. 13(B) is a view illustrating a state where piezoelectric yarns 1 repel each other and a piezoelectric yarn 1 and a piezoelectric yarn 2 attract each other.

FIG. 14 is a view illustrating a woven fabric in which wefts and warps are arranged.

FIG. 15(A) is a plan view of a laminated cloth 100E formed by laminating a plurality of cloths and FIG. 15(B) is a cross-sectional view thereof.

FIG. 16(A) is a plan view of a laminated cloth 100E formed by laminating a plurality of cloths and FIG. 16(B) is a cross-sectional view thereof.

FIG. 17(A) is an exploded perspective view of a laminated cloth 100F that secures heat retention and FIG. 17(B) is a plan view thereof.

FIG. 18(A) and FIG. 18(B) are cross-sectional views of a laminated cloth 100F.

FIG. 19(A) and FIG. 19(B) are cross-sectional views of a laminated cloth 100G.

FIG. 20(A) and FIG. 20(B) are cross-sectional views of a laminated cloth 100H.

### DETAILED DESCRIPTION OF THE INVENTION

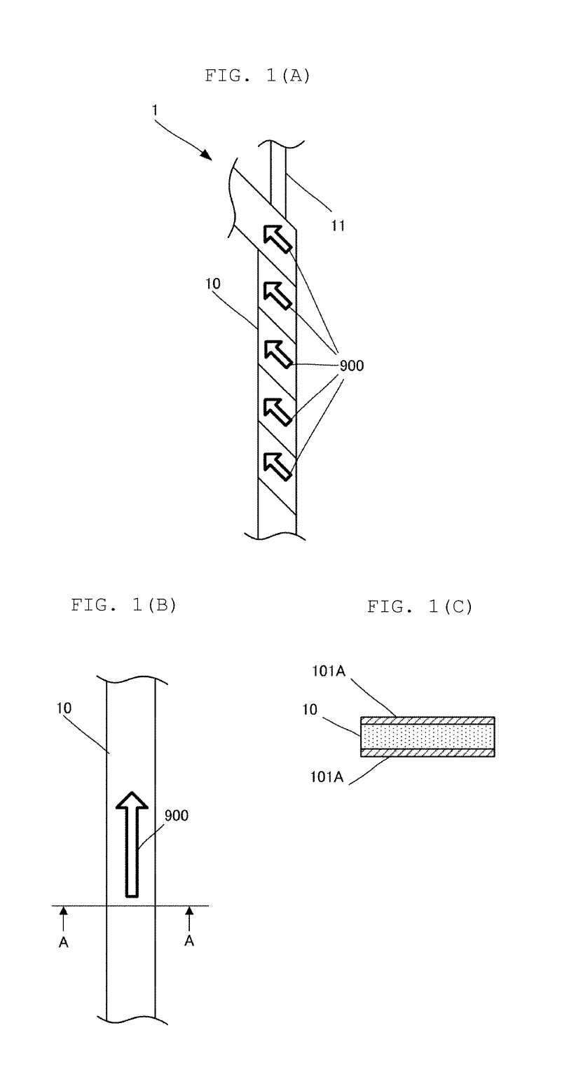

FIG. 1(A) is a partially exploded view illustrating the configuration of a piezoelectric yarn 1 and FIG. 1(B) is a plan view of a piezoelectric film 10. FIG. 1(C) is a cross-sectional view of the piezoelectric film 10 (a cross-sectional view taken along line A-A shown in FIG. 1(B)). The piezoelectric yarn 1 is an example of a charge generation fiber (charge generation yarn) that generates charges by input of external energy.

The piezoelectric yarn 1 is made by winding a piezoelectric film 10 around a core yarn 11. The piezoelectric film 10 is an example of a piezoelectric body. The core yarn 11 is appropriately selected from natural fibers or chemical fibers. Examples of the natural fiber include plant fiber, animal fiber, or polylactic acid. Examples of the plant fiber include cotton or hemp. When polylactic acid is used for the core yarn 11, the core yarn 11 does not need to be particularly a piezoelectric polylactic acid. As described later, when polylactic acid is used for the piezoelectric film 10, the piezoelectric film 10 has a high affinity for the core yarn 11 because they are made of the same material. Examples of the chemical fiber include synthetic fiber, glass fiber, or carbon fiber. Chemical fibers are sturdier than natural fibers.

The core yarn 11 may be a conductive yarn having conductivity. In the case of using a conductive yarn as the core yarn 11, when the piezoelectric properties of the piezoelectric yarn 1 are evaluated, an electric charge generated on the piezoelectric yarn 1 can be measured using an electrode formed on a part of the periphery of the piezoelectric yarn 1 and the core yarn 11. This allows the piezoelectric performance of the piezoelectric film 10 that is used on the piezoelectric yarn 1 to be checked. Further, the conductive yarns are short-circuited to each other to thereby clearly form a circuit among the yarns, so that an electric field generated between the surfaces of the yarns is remarkably increased. In the case of using a conductor for the core yarn 11, when an electric current is passed through the core yarn 11, even a configuration in which an insulator other than the piezoelectric film 10 is wound around the core yarn 11, a thread which generates charges by external energy can be achieved.

The core yarn 11 is not an essential component. Even without the core yarn 11, it is possible to helically twist the piezoelectric film 10 to produce a piezoelectric yarn (twisted yarn). In the absence of the core yarn 11, the twisted yarn becomes a hollow yarn and the heat retaining performance is improved. Further, it is possible to increase the strength of the twisted yarn by impregnating the twisted yarn itself with a bonding agent.

The piezoelectric film 10 is made of, for example, a piezoelectric polymer. Some piezoelectric films are pyroelectric and some are not. For example, PVDF (polyvinylidene fluoride) is pyroelectric and generates charges due to temperature change. The piezoelectric body having pyroelectricity such as PVDF generates charges on its surface due to heat energy of the human body. In a piezoelectric body having pyroelectricity, charges can be generated not only when expansion and shrinkage are applied but also due to change in temperature.

Polylactic acid (PLA) is a piezoelectric film having no pyroelectricity. Polylactic acid is uniaxially stretched to have piezoelectric properties. Polylactic acid includes PLLA, in which an L-form monomer is polymerized, and PDLA, in which a D-form monomer is polymerized.

Polylactic acid is a chiral polymer and its main chain has a helical structure. Polylactic acid exhibits piezoelectricity when it is uniaxially stretched and molecules thereof are thereby oriented. When the degree of crystallization is further increased by further applying heat treatment, the piezoelectric constant increases. A piezoelectric film 10 made of uniaxially stretched polylactic acid has tensor components of d₁₄ and d₂₅ as piezoelectric strain constants, when the thickness direction is defined as a first axis, the stretching direction 900 is defined as a third axis, and the direction orthogonal to both the first axis and the third axis is defined as a second axis. Accordingly, polylactic acid generates charges when a strain occurs in a direction at an angle of 45 degrees to the uniaxially stretching direction.

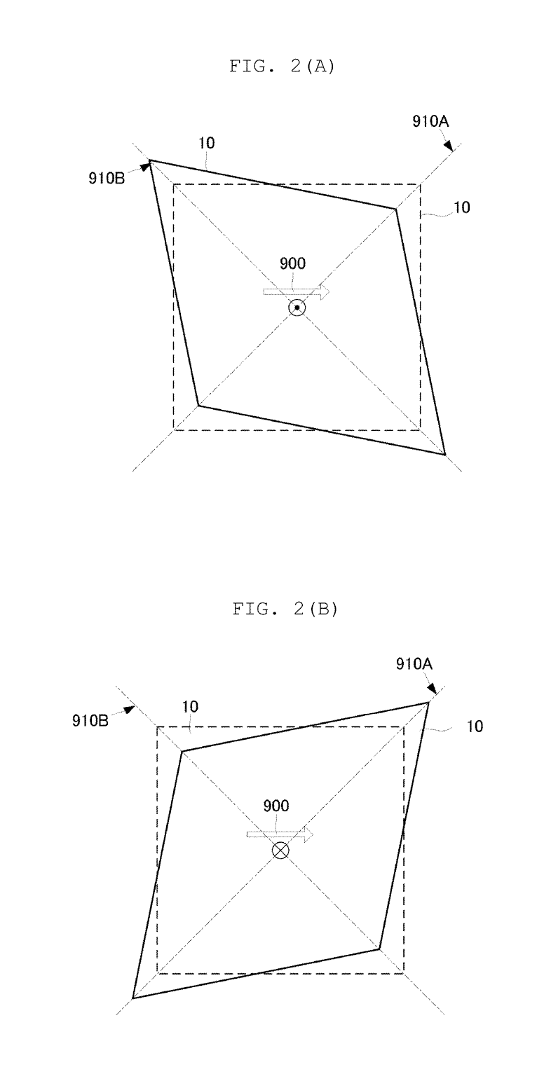

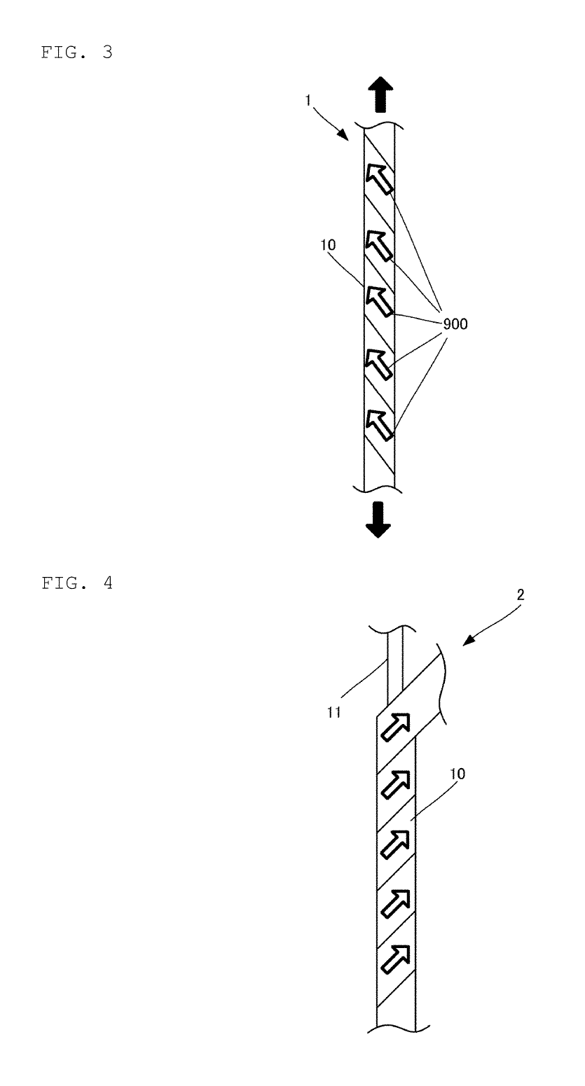

FIG. 2(A) and FIG. 2(B) are views showing a relationship of a uniaxially stretching direction of polylactic acid, an electric field direction, and a deformation of a piezoelectric film 10. As shown in FIG. 2(A), when the piezoelectric film 10 shrinks in a direction of a first diagonal line 910A and stretches in a direction of a second diagonal line 910B perpendicular to the first diagonal line 910A, an electric field is produced in a direction from the back plane to the front plane of the paper. That is, the piezoelectric film 10 generates negative charges on the front plane of the paper. As shown in FIG. 2(B), even when the piezoelectric film 10 stretches in the first diagonal line 910A and shrinks in the second diagonal line 910B, charges are generated, but the polarity is reversed, and an electric field is produced in a direction from the front plane to the back plane of the paper. That is, the piezoelectric film 10 generates positive charges on the front plane of the page.

Since polylactic acid generates piezoelectric properties due to molecular orientation processing by stretching, it does not need to be subjected to polling processing as do other piezoelectric polymers such as PVDF or piezoelectric ceramic. Uniaxially stretched polylactic acid has a piezoelectric constant of approximately 5 to 30 pC/N, which is an extremely high piezoelectric constant among polymers. Furthermore, the piezoelectric constant of polylactic acid does not vary with time and is extremely stable.

The piezoelectric film 10 is produced by cutting a sheet of the uniaxially stretched polylactic acid as described above into a piece having, for example, a width of approximately 0.5 to 2 mm. As shown in FIG. 1(B), the stretching direction 900 of the piezoelectric film 10 corresponds to the longitudinal direction. As shown in FIG. 1(A), the piezoelectric film 10 is made into the piezoelectric yarn 1 of a left-twisted yarn (hereinafter referred to as S yarn) in which the piezoelectric film 10 is twisted around the core yarn 11 to the left. The stretching direction 900 is angled at 45 degrees leftward with respect to the axial direction of the piezoelectric yarn 1.

Accordingly, as shown in FIG. 3, when an external force is applied to the piezoelectric yarn 1, the piezoelectric film 10 becomes in the state as shown in FIG. 2(A), which in turn generates negative charges on a surface of the piezoelectric yarn 1.

Thus, when an external force is applied, the piezoelectric yarn 1 generates negative charges on its surface and positive charges at the inside thereof. Therefore, the piezoelectric yarn 1 produces an electric field due to the potential difference generated by these charges. The electric field leaks to even adjacent spaces to form an electric field associated with other portions. When the potential produced in the piezoelectric yarn 1 comes close to an object having a given potential adjacent thereto, for example, a prescribed potential (including a ground potential) of a human body or the like, an electric field is produced between the piezoelectric yarn 1 and the object.

Conventionally, it has been known that the proliferation of bacteria or fungi can be inhibited by an electric field (see, for example, Tetsuaki Doito, Hiroshi Koryo, Hideaki Matsuoka, Junichi Koizumi, Kodansha: Microbial Control-Science and Engineering; see for example, Koichi Takagi, Application of High Voltage Plasma Technology to Agriculture Food Field, and see J. HTSJ, Vol. 51, No. 216). A potential which produces the electric field may cause an electric current to flow in a current path formed due to humidity or the like, or in a circuit formed through a local phenomenon of microdischarge.

This electric current is considered to weaken bacteria and inhibit the proliferation of bacteria. The bacteria as used in the present embodiment include germs, fungi, or microorganism such as mites and fleas.

Therefore, the piezoelectric yarn 1 directly exerts an antibacterial effect or a sterilizing effect with an electric field that is formed in the vicinity of the piezoelectric yarn 1, or with an electric field that is generated when the piezoelectric yarn 1 is brought close to an object with a prescribed electric potential, such as a human body. Alternatively, the piezoelectric yarn 1 allows an electric current to flow when it comes close to an object having a given potential of another adjacent fiber, a human body or the like with moisture such as sweat interposed therebetween. The piezoelectric yarn 1 may also directly exert an antibacterial effect or a sterilizing effect due to such an electric current. Alternatively, the piezoelectric yarn 1 may indirectly exert an antibacterial effect or a sterilizing effect due to active oxygen species which oxygen contained in moisture is converted into by the action of electric current or voltage, radical species generated by the interaction with an additive contained in the fibers or by catalysis, or other antibacterial chemical species (amine derivatives or the like). Alternatively, stress environment caused by the presence of the electric field or electric current may produce oxygen radicals in cells of bacteria. This may allow the piezoelectric fibers 5 to indirectly exert an antibacterial effect or a sterilizing effect. As the radicals, superoxide anion radical (active oxygen) or hydroxy radical may be generated.

The above-described charge generation yarn including a charge generation fiber that generates charges by external energy can be applied to various products such as clothing articles and medical members. For example, the charge generation yarn can be used for underwear (especially socks), towels, insoles of shoes, boots, and the like, general sportswear, hats, beddings (including futon, mattresses, sheets, pillows, pillowcases, and the like), toothbrushes, dental floss, various types of filters (filters of water purifiers, air conditioners, air purifiers, or the like), stuffed animals, pet-related items (pet mats, pet clothes, inners for pet clothes), various types of mats (for feet, hands, toilet seat, and the like), curtains, kitchen utensils (sponges, dishcloths, or the like), seats (seats of cars, trains, or airplanes), sofas, bandages, gauze, masks, sutures, clothes for doctors and patients, supporters, sanitary goods, sporting goods (wear and inner gloves, gauntlets for use in martial arts, or the like), or packaging materials.

Of the clothing, in particular, the socks (or supporters) are inevitably expanded and contracted along joints by movements such as walking, and the piezoelectric yarn 1 thus generates charges with high frequency.

In addition, although socks absorb moisture such as sweat and serve as hotbeds for proliferation of bacteria, the piezoelectric yarn 1 can inhibit the proliferation of bacteria, and thus has a remarkable effect for bacterium-countermeasure.

In the antibacterial fiber of the present embodiment, the main surface of the piezoelectric film 10 is covered with a water-resistant member 101A as shown in FIG. 1(C). The water-resistant member 101A is made of, for example, an acrylic resin or a silicon-based resin. Therefore, adhesion of stains (for example, rain stains) to the piezoelectric film 10 can be prevented, and resistance to water at the time of washing can be improved.

In the example of FIG. 1(C), both main surfaces of the piezoelectric film 10 are covered, but it is sufficient if at least the main surface on the side disposed outside the piezoelectric yarn 1 is covered with the water-resistant member 101A. It is preferable that the thickness of the water-resistant member 101A is small so that the deformation of the piezoelectric film 10 is not hindered and the water resistance function is provided (for example, about 5 μm). Although both main surfaces are covered in FIG. 1(C), it is preferable that they be covered with the water-resistant member 101A so as to cover the periphery of the piezoelectric film as well as the side surface. In another possible embodiment, a thin hole is provided in the piezoelectric film 10 along its longitudinal direction and the water-resistant members 101A covering both main surfaces of the piezoelectric film 10 are directly connected together through the thin hole. By employing such a structure, it is possible to improve the adhesion between the piezoelectric film 10 and the water-resistant member 101A, and moreover, by providing thin holes, it is possible to allow the state of expansion and shrinkage in the piezoelectric film 10 to be partially different (that is, since sites where charge generation is strong are partially formed, an antibacterial effect can be exerted).

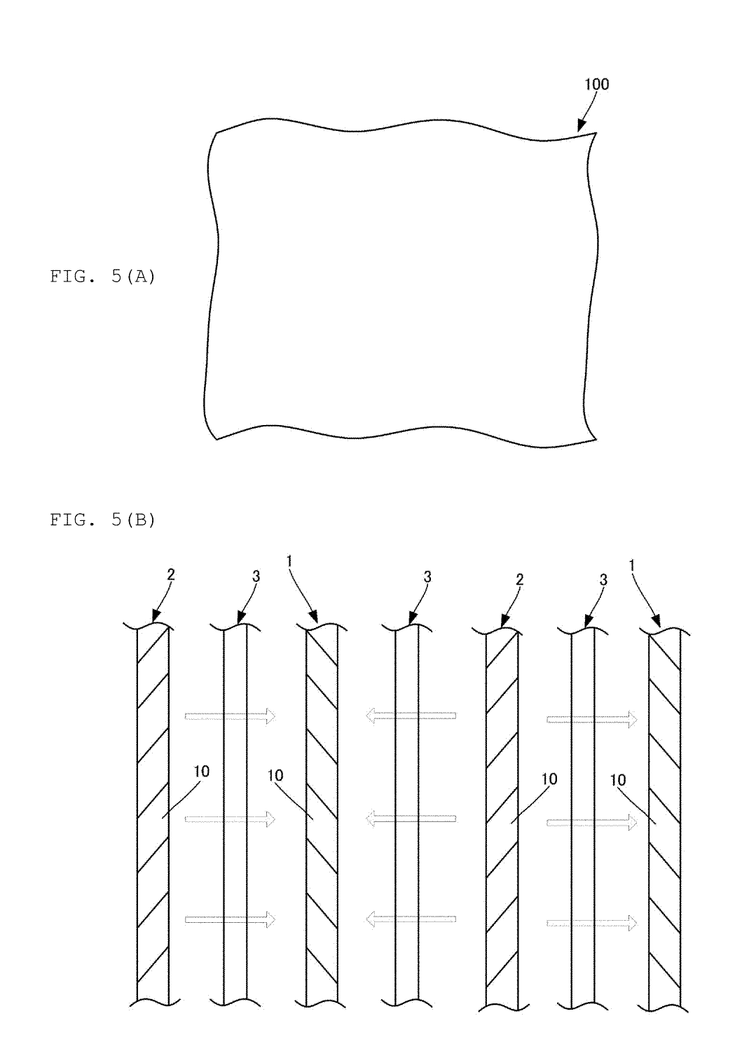

As the piezoelectric yarn, it is possible to use a piezoelectric yarn 2 that is a right-twisted yarn (hereinafter referred to as a Z yarn) as illustrated in FIG. 4. Since the piezoelectric yarn 2 is a Z yarn, the stretching direction 900 thereof is tilted 45 degrees rightward with respect to the axial direction of the piezoelectric yarn 1. Accordingly, when an external force is applied to the piezoelectric yarn 2, the piezoelectric film 10 comes into a state illustrated in FIG. 2(B) and generates positive charges on its surface and negative charges at the inside thereof. Therefore, the piezoelectric yarn 2 generates an electric field when it is brought close to an object with a prescribed potential (including a ground potential), such as a human body. Alternatively, the piezoelectric yarn 2 allows an electric current to flow when it comes close to an object with a prescribed potential (including a ground potential), such as a human body, with moisture such as sweat interposed therebetween.

The piezoelectric yarn is produced by any known method. For example, the following method is adoptable: a method of extruding and shaping, for example, a piezoelectric polymer to be made into a fibrous form as a fiber, as well as a covering yarn including a slit film; a method of melt-spinning a piezoelectric polymer to be made into a fibrous form (for example, a spinning and drawing method in which a spinning step and a drawing step are performed separately from each other, a direct drawing method in which a spinning step and a drawing step are linked to each other, a POY-DTY method in which a false twisting step can also be attained at the same time, or a super high speed spinning method in which the spinning speed is made high); a method of dry- or wet-spinning a piezoelectric polymer to be made into a fibrous form (for example, a phase-separating method or dry- or wet-spinning method of dissolving a polymer, which is a raw material, into a solvent, and extruding out the solution through a nozzle to be made into a fibrous form, a gel spinning method of making a polymer into a gel form in the state the polymer contains a solvent, so as to be evenly made into a fibrous form, or a liquid crystal spinning method of using a solution of a liquid crystal or a melted body thereof to make the liquid crystal into a fibrous form); or a method of spinning a piezoelectric polymer electrostatically to be made into a fibrous form.

Many bacteria have negative charges. Therefore, a cloth including the piezoelectric yarn 2 allows most of the bacteria to be attracted with the positive charges generated.

Furthermore, the cloth including the piezoelectric yarn 2 can inactivate bacteria having negative charges by using positive charges. In this manner, the cloth using the piezoelectric yarn that generates positive charges on its surface has a high effect as a piezoelectric yarn for bacterium-countermeasure.

Furthermore, the piezoelectric yarn 1 or the piezoelectric yarn 2 (or a cloth including at least one of these) has the following use applications other than bacterium-countermeasure.

(1) Bioactive Piezoelectric Yarn

Many tissues constituting a living body have piezoelectric properties. For example, collagen constituting a human body, which is a kind of protein, is included a lot in blood vessels, dermis, ligaments, tendons, bones, cartilages, and the like. Collagen is a piezoelectric body, and a tissue with collagen oriented may exhibit a great deal of piezoelectric properties. Many reports have already been made on the piezoelectric properties of bones (see, for example, Eiichi Fukada, Piezoelectricity of Biopolymer, Polymer Vol. 16 (1967) No. 9 p 795-800, etc.). Therefore, when the cloth including the piezoelectric yarn 1 or the piezoelectric yarn 2 generates an electric field, and alternates the electric field or changes the strength of the electric field, the piezoelectric body of a living body vibrates due to the inverse piezoelectric effect. The alternated electric field or the change in the electric field strength, generated by the piezoelectric yarn 1 and/or the piezoelectric yarn 2, applies a minute vibration to a part of a living body, for example, a capillary blood vessel or dermis, thereby making it possible to encourage improvement in blood flow through the part. Thus, there is a possibility that the healing of skin diseases, wounds, and the like may be promoted. Therefore, the piezoelectric yarn functions as a bioactive piezoelectric yarn. The transducer that has a plurality of piezoelectric yarns and conductive yarns made into a knitted fabric or a woven fabric and senses that displacement is applied to the knitted fabric or the woven fabric is disclosed in WO2015/159832. In this case, all of the conductive yarns are connected to a detection circuit, and there is necessarily a pair of conductive yarns for one piezoelectric yarn. According to WO2015/159832, when charges are generated in the piezoelectric yarns, electrons move through the conductive yarns, and immediately neutralize the charges generated. According to WO2015/159832, the detection circuit captures the electric current through the movement of the electrons, and outputs the electric current as a signal. Therefore, in this case, because the generated electric potential is canceled immediately, a strong electric field is not formed between the piezoelectric yarn and the conductive yarn and between the piezoelectric yarn and the piezoelectric yarn, and any healing effect is not exerted.

(2) Piezoelectric Yarn for Substance Adsorption

As described above, the piezoelectric yarn 1 generates negative charges when external force is applied.

The piezoelectric yarn 2 generates positive charges when external force is applied. Therefore, the piezoelectric yarn 1 attracts a substance having a positive charge (e.g., particles such as pollen) and the piezoelectric yarn 2 attracts a substance having a negative charge (e.g., harmful substances such as yellow dust). Accordingly, it is possible for the cloth 100 including the piezoelectric yarn 1 or 2 to attract fine particles such as pollen or yellow dust, when the cloth is applied to a medical supply such as a mask. The transducer that has a plurality of piezoelectric yarns and conductive yarns made into a knitted fabric or a woven fabric and senses that displacement is applied to the knitted fabric or the woven fabric is disclosed in WO2015/159832. In this case, all of the conductive yarns are connected to a detection circuit, and there is necessarily a pair of conductive yarns for one piezoelectric yarn. According to WO2015/159832, when charges are generated in the piezoelectric yarns, electrons move through the conductive yarns, and immediately neutralize the charges generated. According to WO2015/159832, the detection circuit captures the electric current through the movement of the electrons, and outputs the electric current as a signal. Therefore, in this case, because the generated electric potential is canceled immediately, a strong electric field is not formed between the piezoelectric yarn and the conductive yarn and between the piezoelectric yarn and the piezoelectric yarn, and any adsorption effect is not exerted.

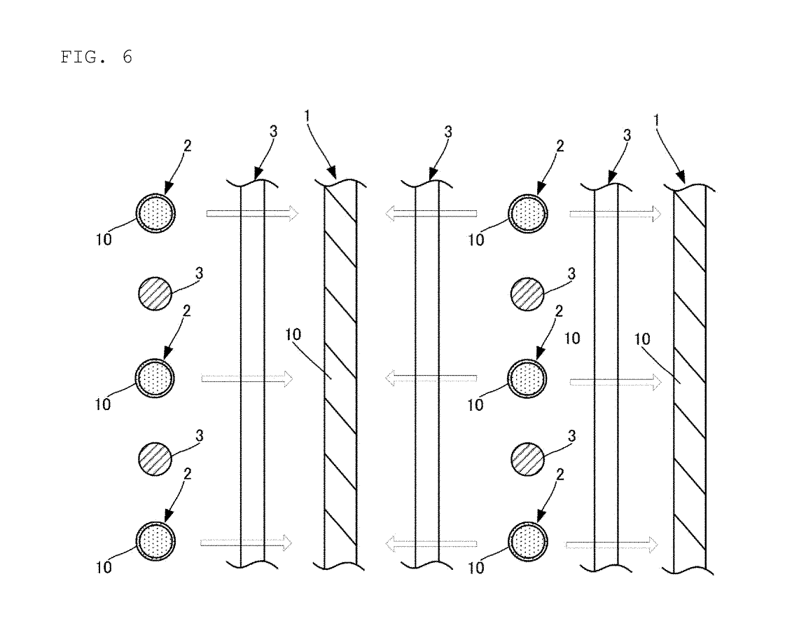

FIG. 5(A) is a schematic plan view of a cloth 100, and FIG. 5(B) is a view showing electric fields between the yarns. The cloth 100 is woven of the piezoelectric yarn (first yarn) 1, the piezoelectric yarn (second yarn) 2, and an ordinary yarn 3. The ordinary yarn 3 is a yarn which is not provided with a piezoelectric body and is equivalent to a dielectric. The ordinary yarn 3, the ordinary yarn 3 is a yarn which is not provided with a piezoelectric body and is equivalent to a dielectric. The ordinary yarn 3, however, is not an essential component in the present invention.

In the example of FIG. 4(B), the piezoelectric yarn 1, the piezoelectric yarn 2, and the ordinary yarn 3 are arranged in parallel. Each of the piezoelectric yarns 1 and 2 is arranged at a prescribed spaced interval with the ordinary yarn 3 interposed therebetween, the ordinary yarn being equivalent to a dielectric. The polarities of charges generated are different from each other between the piezoelectric yarn 1 and the piezoelectric yarn 2. The potential difference at each point is defined by an electric field coupling circuit formed by complicatedly intertwining yarns, or a circuit formed by a current path which is accidentally formed in the yarn due to moisture or the like. Accordingly, when external force is applied to the yarns, an electric field represented by outlined arrows in the figure is generated between the piezoelectric yarn 2 generating positive charges and the piezoelectric yarn 1 generating negative charges. However, the ordinary yarn 3 is not an essential constituent. Even when the ordinary yarn 3 is not used, an electric field is generated between the piezoelectric yarn 1 and the piezoelectric yarn 2. When the piezoelectric yarn 1 (S yarn) and the piezoelectric yarn 2 (Z yarn) are formed from PLLA, the piezoelectric yarn 1 alone has a negative electric potential on the surface and a positive electric potential inside when a tension is applied. Conversely, the piezoelectric yarn 2 has a positive electric potential on the surface and a negative electric potential inside. When these yarns are brought close to each other, the nearby parts (surfaces) tend to have the same electric potential. In this case, the nearby parts of the piezoelectric yarn 1 and the piezoelectric yarn 2 reach 0 V, and the positive electric potential inside the piezoelectric yarn 1 is further increased so as to keep the original potential difference, and likewise, the negative electric potential inside the piezoelectric yarn 2 is further decreased. In a cross section of the piezoelectric yarn 1, an electric field directed mainly outward from the center is formed, and in a cross section of the piezoelectric yarn 2, an electric field directed mainly inward from the center is formed. In spaces around these yarns, leakage electric fields are created, and the leakage electric fields are bonded to each other to create a strong electric field between the piezoelectric yarns 1 and 2.

The piezoelectric yarn 1 is arranged very closely to the piezoelectric yarn 2, so that the distance between the piezoelectric yarns 1 and 2 is approximately zero. The strength of any electric field, as is represented by E=V/d, becomes larger in inverse proportion to the distance between the substances that generate charges, and thus, the strength of the electric field generated by the cloth 100A becomes a very large value. The electric field is created by mutual bonding between electric fields generated inside the piezoelectric yarn 1 and electric fields generated inside the piezoelectric yarn 2. As the case may be, a circuit may be formed as an actual current path due to moisture containing an electrolyte such as sweat. In a fiber knitted cloth, fibers are complicatedly entangled with each other, so that an electric field generated in one portion of the piezoelectric yarn 1 and an electric field generated in another portion of the piezoelectric yarn 1 may be mutually combined. Likewise, an electric field generated in one portion of the piezoelectric yarn 2 and an electric field generated in another portion of the piezoelectric yarn 2 may be mutually combined. Even in the case where the strength of the electric field is macroscopically none or very weak, strong electric fields having conflicting vector directions may be microscopically assembled. These phenomena may be similarly described with a cloth formed of the piezoelectric yarn 1 alone, a cloth formed of the piezoelectric yarn 2 alone, or a cloth in which an ordinary yarn or a conductive yarn is knitted together with these clothes.

Thus, the cloth 100 functions as a cloth that generates an electric field. In the cloth 100, an electric current may flow between the piezoelectric yarn 1 and the piezoelectric yarn 2 with moisture such as sweat interposed therebetween. By this electric field or electric current, the cloth may directly exhibit an antibacterial effect or a sterilizing effect. Alternatively, the piezoelectric yarn 1 may indirectly exert an antibacterial effect or a sterilizing effect due to active oxygen species which oxygen contained in moisture is converted into by the action of electric current or voltage, radical species generated by the interaction with an additive contained in the fibers or by catalysis, or other antibacterial chemical species (amine derivatives or the like). Alternatively, oxygen radicals may be produced in cells of bacteria by a stress environment based on the presence of an electric field or an electric current, and in this way, an antibacterial effect or a sterilizing effect may be indirectly exhibited.

An example in which the piezoelectric yarn 1 is different in the polarity of generated charges from the piezoelectric yarn 2 has been described in the above example. However, even when piezoelectric yarns having the same polarity are used, an electric field is generated or an electric current flows via a conductive medium, when a potential difference exists in the space of the piezoelectric yarn 1 and the piezoelectric yarn 2.

The cloth 100 exhibits an antibacterial or sterilizing effect by an electric field which the cloth itself generates and a change in the strength thereof, or by the electric current. Alternatively, the cloth exhibits an antibacterial or sterilizing effect by, for example, radical species generated by the effect of the electric current or voltage. The cloth 100 may also include a conductive fiber that elutes out therefrom a metal ion. In this case, in the cloth 100, in addition to an antibacterial or sterilizing effect by the electric field, the antibacterial or sterilizing effect is further enhanced by the metal ion eluted out from the conductive yarn.

About the cloth 100, even when the piezoelectric yarn 1 has a site where no charge is generated, this cloth exhibits an antibacterial or sterilizing effect by the metal ion eluted out from the conductive yarn.

A clothing article using the cloth 100 or a medical member using this clothing article exhibits an antibacterial or sterilizing effect in the same manner. The clothing article using the cloth 100, particularly, socks (or supporters) using the same also produce a remarkable advantageous effect for bacterium-countermeasure as described above. In the same manner as the above-mentioned piezoelectric yarn that acts on a living body or the piezoelectric yarn for substance-adsorption, the cloth 100 also functions as a piezoelectric cloth that acts on a living body or a piezoelectric cloth for substance-adsorption.

The cloth 100 exhibits an antibacterial or sterilizing effect through an electric field or electric current generated by the piezoelectric yarns 1 and 2, which constitute this cloth itself, so that this cloth exhibits an antibacterial or sterilizing effect against bacteria moved to the cloth 100. On the skin of a human body, normal bacterial flora is present, which fulfills a role necessary for keeping the skin surface in a normal state; whereas small is the possibility that the cloth 100 directly kills the normal bacterial flora. Therefore, there is only a small risk of affecting the normal bacterial flora on the skin, and thus, the cloth 100 is higher in safety.

On the skin of a human body, normal bacterial flora is present, which fulfills a role necessary for keeping the skin surface in a normal state; whereas small is the possibility that the cloth 100 directly kills the normal bacterial flora. Therefore, there is only a small risk of affecting the normal bacterial flora on the skin, and thus, the cloth 100 is higher in safety.

Even in the cloth 100 which is an embodiment in which piezoelectric yarns 1, piezoelectric yarns 2, and ordinary yarns 3 are arranged to cross each other as illustrated in FIG. 6, electric fields are generated in positions where the piezoelectric yarn 1 crosses the piezoelectric yarn 2.

Although the descriptions have been made about a cloth (woven fabric) in which a plurality of yarns including a charge generation yarn are woven into each other in the above-described examples, also in a cloth made of a knitted good (a product in which rings made of a plurality of yarns including a charge generation yarn are hooked or hung with each other), electric fields are generated or an electric current flows in the same manner between the yarns in which a potential difference is generated, and thus, the knitted good produces an antibacterial or sterilizing effect.

As the yarn that generates negative charges on its surface, a Z yarn using PDLA is considered as well as an S yarn using PLLA. In addition, as the yarn that generates positive charges on its surface, an S yarn using PDLA is considered as well as a Z yarn using PLLA.

Although the piezoelectric film is shown as an example of the piezoelectric body in the present embodiment, the piezoelectric body may be a yarn discharged from a nozzle and then stretched (a piezoelectric yarn having an approximately circular cross section or a piezoelectric yarn having a modified cross section). The spinning method therefor may be, for example, wet spinning, dry spinning or melt spinning. For example, a polylactic acid (PLLA) piezoelectric yarn may be prepared by melt spinning, high stretching, or heat treatment (for crystallization). Also in the case of forming such a yarn in which a plurality of PLLA piezoelectric yarns are twisted with each other (a multifilament yarn) and applying a tension to the resulting yarn, negative charges are generated on a surface of an S yarn and positive charges are generated on a surface of a Z yarn. Such a yarn can be merely rendered a twisted yarn without using any core yarn. Such a yarn can be produced at low costs. The number of filaments of the multifilament yarn should be set in view of the use of the yarn. The number of twists is also appropriately set. The filaments may each partially contain therein a filament which is not any piezoelectric body.

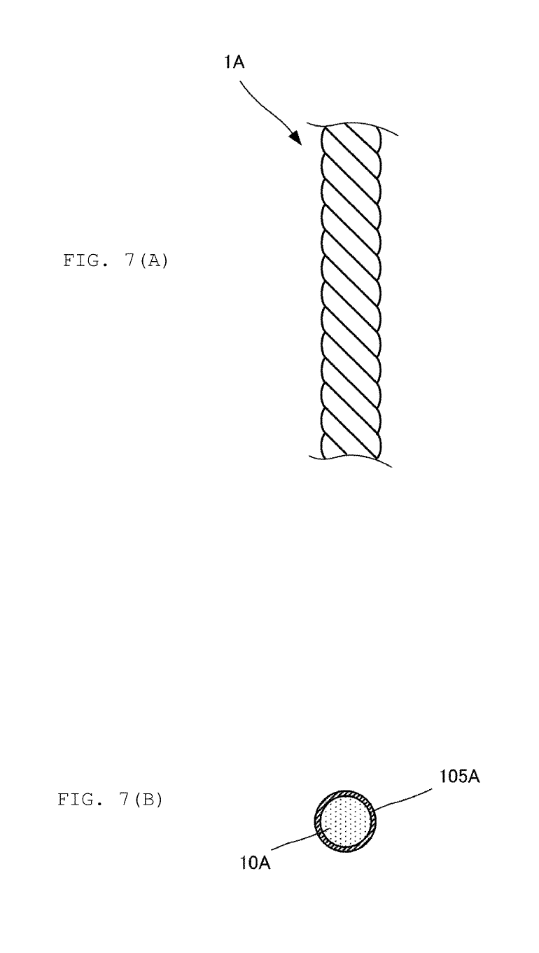

Moreover, the individual filaments may not be uniform in thickness. Thanks to such configurations, a potential distribution produced in the cross section of the yarn deviates to break symmetry, so that an electric field circuit between the S yarn and the Z yarn is readily formed. FIG. 7(A) is a view showing a covering yarn 1A obtained by twisting a piezoelectric fiber 10A having a circular cross section. Also in the case of constructing a covering yarn 1A as shown in FIG. 7(A), negative charges are generated on the surface of the S yarn, and positive charges are generated on the surface of the Z yarn. As shown in FIG. 7(B), the piezoelectric fiber 10A has a cut surface, the entire periphery of which is covered with a water-resistant member 105A. The water-resistant member 105A is also made of, for example, an acrylic resin or a silicon-based resin. Therefore, adhesion of stains (for example, rain stains) to the piezoelectric fiber 10A can be prevented, and resistance to water at the time of washing can be improved.

The water-resistant member 101A or the water-resistant member 105A may have conductivity. In order to impart conductivity to a water-resistant member, there is considered, for example, an embodiment in which the water-resistant member is made of a conductive material (for example, metal). Alternatively, conductivity can be imparted by mixing a material (powder) such as carbon in the water-resistant member.

As described above, the strength of the electric field increases in inverse proportion to the distance between substances which generate charges as represented as E=V/d. When the water-resistant member has conductivity, the charges polarized on the surface of the piezoelectric body reach the surface via the water-resistant member. Therefore, as compared with the case where the water-resistant member is an insulator, when the water-resistant member has conductivity, the interval between the piezoelectric yarns is shortened, so that the strength of the electric field becomes a larger value.

The water-resistant member may further have heat resistance. In this case, when the antibacterial fiber of the present embodiment is used for clothes, resistance to an intense heat such as a dryer and an iron can be improved.

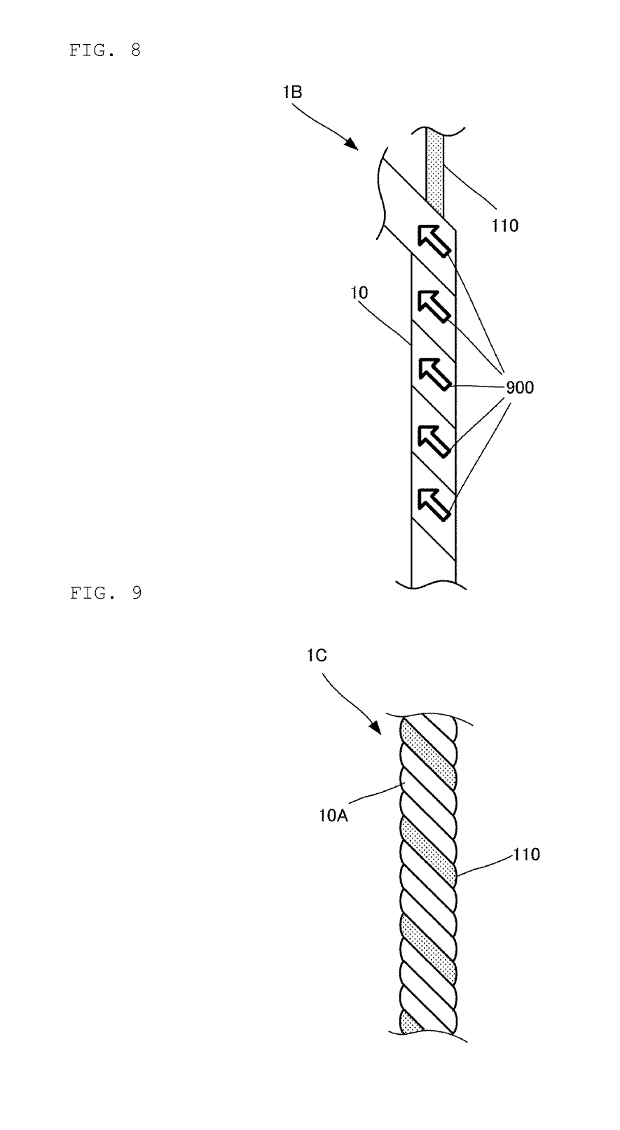

Next, FIG. 8 is a diagram illustrating the configuration of a more elasticized antibacterial fiber 1B.

Conventionally, for antibacterial clothing articles, for example, a fiber to which a drug is attached or a fiber containing a metal such as silver or copper is used as disclosed in Japanese Examined Patent Publication No. 6-84561.

However, fibers using a drug or a metal are difficult to fit sites having complicated shapes such as joints of legs or arms because such fibers are poor in texture and lack elasticity. Therefore, it is difficult to impart antibacterial properties to conventional antibacterial fibers at desired sites thereof.

Thus, it is an object of the antibacterial fiber 1B of the present embodiment to impart antibacterial properties to a desired site such as a site having a complicated shape, such as joints of legs or arms.

The antibacterial fiber 1B of the present embodiment uses an elastic body 110 as the core yarn as shown in FIG. 8. The elastic body 110 is made of, for example, rubber. Therefore, the antibacterial fiber 1B has an improved elasticity as compared with fibers relatively low in elasticity, such as cotton or hemp. Although the antibacterial fiber is drawn like a single core yarn in FIG. 8, it may be a single core yarn or a bundle of a plurality of thin elastic bodies.

Thus, a clothing article using the antibacterial fiber 1B of the present embodiment can be fitted to sites having complicated shapes, such as joints of legs or arms. In this case, the antibacterial fiber 1B fits the body and the clothing article is stretched and shrunk by the elastic body 110 even when a leg or the like has slightly moved, so that charges are generated more often. In particular, since socks always expand and shrink along joints, the socks frequently generate charges.

Further, with the configuration using the elastic body 110 for the core yarn, the antibacterial fiber 1B can be used throughout a clothing article such as socks or only at sites that frequently expand and shrink, such as toes and heels. When using only at sites that frequently expand and shrink such as toes and heels, materials with good texture, such as cotton, can be used for other sites, so that it is possible to improve the comfort in wearing of socks as a whole while maintaining the antibacterial effect.

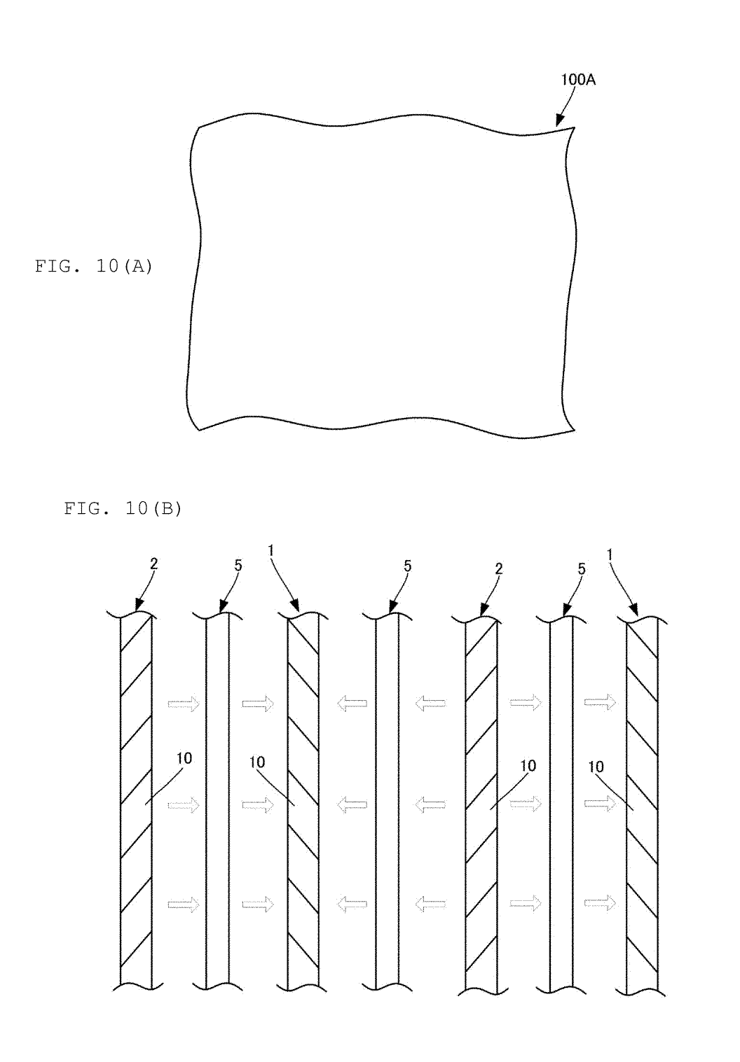

However, even in the case of constituting a covering yarn 1C formed by twisting an elastic body 110 and a piezoelectric fiber 10A having a circular cross section as illustrated in FIG. 9, the elasticity of the antibacterial fiber is improved as compared with fibers relatively low in elasticity, such as cotton and hemp.

Next, FIG. 10(A) is a schematic plan view of a cloth 100A, and FIG. 10(B) is a view illustrating an electric field generated between individual yarns. In the cloth 100A, piezoelectric yarns (first yarns) 1, piezoelectric yarns (second yarns) 2, and conductive yarns 5 are woven together. The conductive yarn 5 is made of a conductor (conductive fiber). The conductive fiber may be, for example, a fiber purely made of metal (a fine wire), a slit ribbon, a polyester fiber having an electroless-plated surface, or a product obtained by making a polyester film having vapor-deposited electrodes into a slit ribbon form, and that is a fiber sturdier than antibacterial fibers using a piezoelectric body.

A cloth including antibacterial fibers may be used for a product that is prone to wear or break, such as socks. The above-described cloth 100 is strong against wear and breakage when tough fibers such as rayon are used for the ordinary yarn 3. In addition, when tough fibers such as rayon are used, it is easier to knit/weave tough fibers than metal fibers and it is possible to afford tough cloth albeit less than metal fibers.

On the other hand, when conductive yarns are used for the ordinary yarn, the conductive yarn 5 has a prescribed electric potential (including a ground potential) because the conductive yarn is a conductor. Therefore, when an external force is applied to the piezoelectric yarn 1 or the piezoelectric yarn 2, the potential difference between the conductive yarn 5 having a prescribed electric potential and the piezoelectric yarn 1 that generates negative charges or the piezoelectric yarn 2 that generates positive charges causes an electric field therebetween.

The piezoelectric yarn 1 and the conductive yarn 5 (and the piezoelectric yarn 2 and the conductive yarn 5) are arranged closer to each other than the state where the ordinary yarn 3 is interposed. Therefore, the strength of the electric field generated by the cloth 100A is a relatively large value.

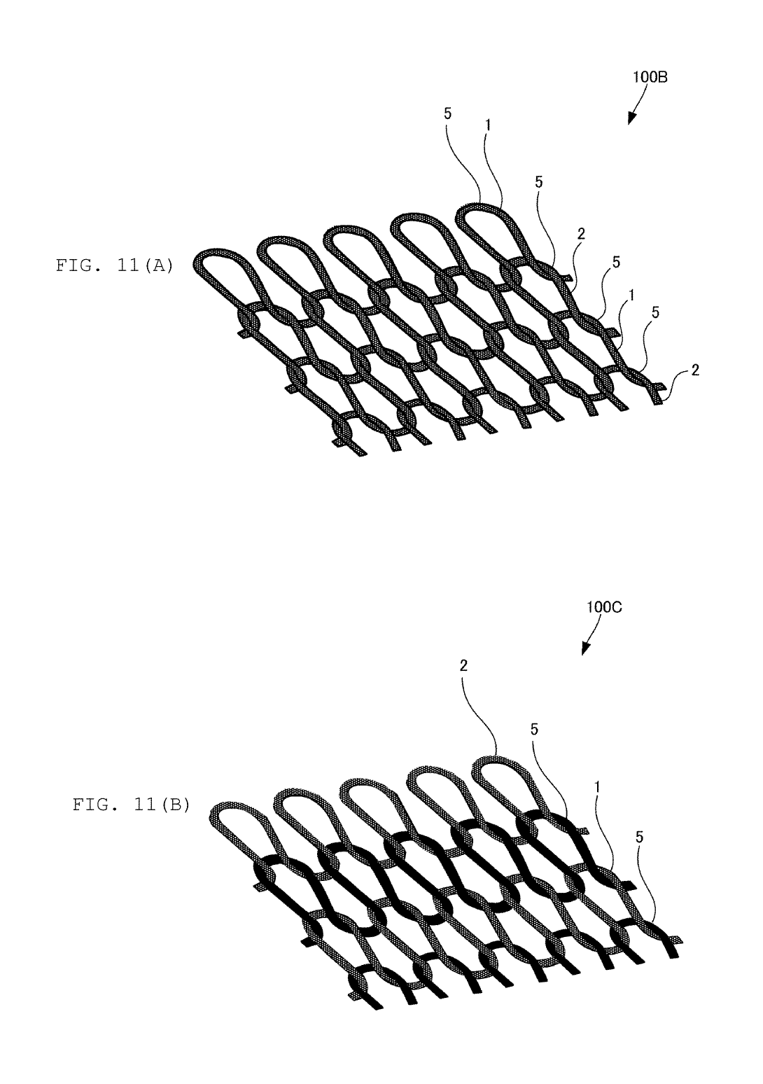

FIG. 11(A) is a diagram showing the configuration of a cloth 100B made of a knitted fabric. As shown in FIG. 11(A), the cloth 100B is constituted by combining each yarn (the piezoelectric yarn 1 and the piezoelectric yarn 2) with the conductive yarn 5. Further, it is also possible to form a cloth 100C in which a knitted fabric is constituted by knitting the piezoelectric yarn 1, the piezoelectric yarn 2 and the conductive yarn 5 together as shown in FIG. 11(B).

By being combined with the conductive yarn 5, either a woven fabric or a knitted fabric can constitute a cloth that is relatively sturdy and does not lower the strength of an electric field. If the electric field strength may be somewhat weak, sturdy fibers such as rayon may be used instead of the conductive yarns. In this case, a certain degree of antibacterial effect can be obtained and texture can be made even as compared with the case of using conductive yarns.

In addition, conductive yarns and sturdy fibers such as rayon may be used in combination.

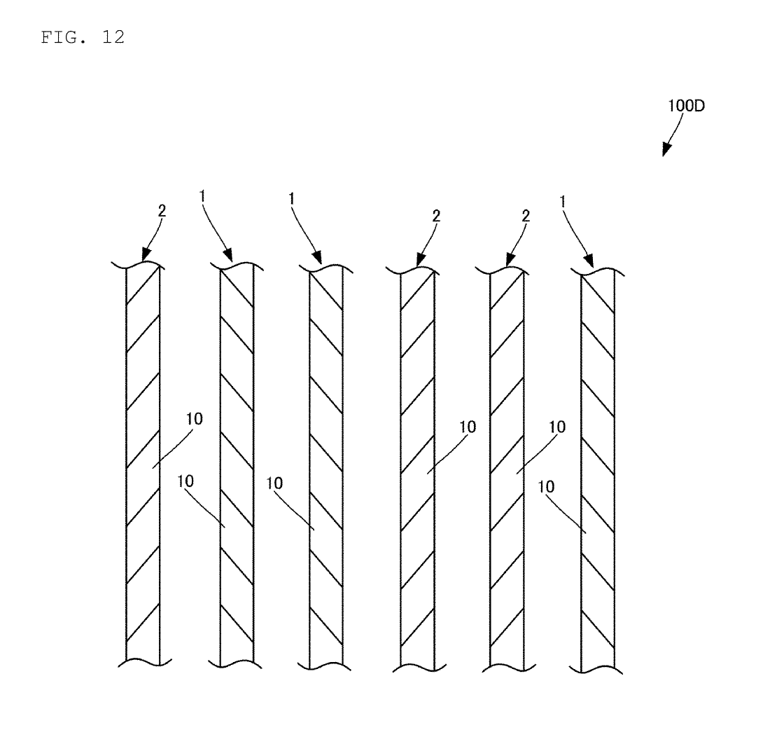

Next, FIG. 12 is a view showing a configuration of a cloth 100D having both air permeability and heat retention.

Conventionally, there have been proposed clothing articles improved in air permeability by providing through holes as disclosed in, for example, Japanese Patent Application Laid-Open Nos. 2000-166606 and 10-248604.

However, the provision of the through hole causes a problem of deterioration of heat retention.

Thus, the cloth 100D of the present embodiment aims to have both air permeability and heat retention.

In the cloth 100D, the piezoelectric yarns 1 and the piezoelectric yarns 2 are arranged in parallel as shown in FIG. 12. However, next to a certain piezoelectric yarn 1, another piezoelectric yarn 1 and a piezoelectric yarn 2 are arranged. Likewise, next to a certain piezoelectric yarn 2, there are arranged another piezoelectric yarn 2 and a piezoelectric yarn 1. Although no ordinary yarn 3 is shown in this example, an ordinary yarn 3 may be disposed between the respective piezoelectric yarns. Further, a conductive yarn 5 may be disposed between the respective piezoelectric yarns.

As shown in FIG. 13(A), the polarity of charges generated from the piezoelectric yarn 1 differs from that of charges generated from the piezoelectric yarn 2. Therefore, when an external force is applied to these yarns, piezoelectric yarns 1 repel each other and a piezoelectric yarn 1 and a piezoelectric yarn 2 attract each other as shown in FIG. 13(B).

Accordingly, when an external force is applied to the yarns, sites having a large opening are partially formed, so that the air permeability is relatively improved. The space widens at the sites where yarns repel, whereas the space narrows at the sites where yarns attract. That is, the cloth 100D comes to have sites having larger openings and sites having smaller openings. The cloth 100D comes to have both openings through which water vapor and water drops can pass and openings through which neither water vapor nor water drops can pass, so that the cloth can have both air permeability and moisture retention. The intensified the exercise, the stronger the external force on the yarns becomes, and therefore, the cloth 100D comes to have wider spaces between piezoelectric yarns and improved air permeability as the exercise is intensified. On the other hand, when exercise does not occur, heat retention is secured. When exercising, the piezoelectric yarns repel or attract each other, so that tension is applied to the piezoelectric yarns. When not exercising, no charge has been generated in the piezoelectric yarns, so that no tension is applied to the piezoelectric yarns and the piezoelectric yarns are in an initial state (the piezoelectric yarns are equally spaced). Therefore, the cloth 100D is configured to have improved air permeability at a time when air permeability is required such as during exercise and the cloth 100D is also configured to have a high heat retention at a time when heat retention is required such as out of exercise, so that the cloth is configured to have both air permeability and heat retention.

Since the opening area changes depending on the intensity of the exercise, the cloth can maintain a state where users feel comfortable. In addition, a structure like that shown in FIG. 12 may be used for the entire clothing article, or when being used only for a joint part which is prone to be sweaty, such as an axilla, a material having good texture, such as cotton, may be used for other parts. Thus, it is possible to maintain an antibacterial effect and, at the same time, improve the comfortability in wearing of the entire clothing article.

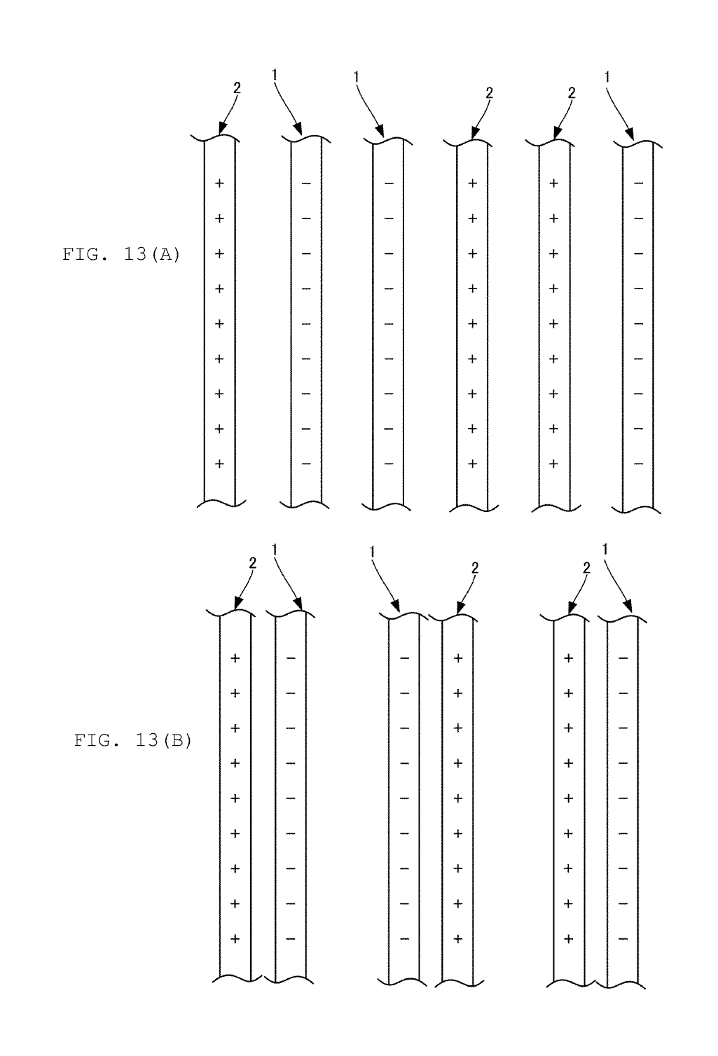

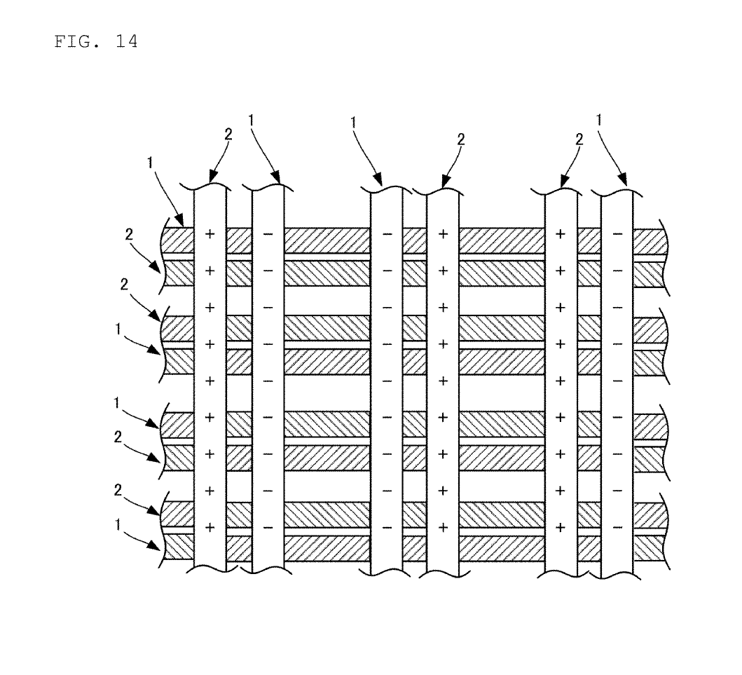

Although the piezoelectric yarns arranged in parallel are shown in FIG. 13(B), even in the case where wefts and warps are arranged as in the fabric shown in FIG. 14, the wefts and the warps repel and attract each other, so that such a fabric is configured to have both air permeability and heat retention. Of course, also in a knitted fabric, next to a certain piezoelectric yarn 1, another piezoelectric yarn 1 and a piezoelectric yarn 2 are arranged, and next to a piezoelectric yarn 2, another piezoelectric yarn 2 and a piezoelectric yarn 1 are arranged, whereby a similar configuration can be realized.

Next, FIG. 15(A) is a plan view of a laminated cloth 100E formed by laminating a plurality of cloths and FIG. 15(B) is a cross-sectional view thereof. In the laminated cloth 100E, the piezoelectric yarns 1, the piezoelectric yarns 2 are arranged in parallel with each other like the cloth 100D illustrated in FIG. 12. Between a piezoelectric yarn 1 and a piezoelectric yarn 2 adjacent to each other, an ordinary yarn 55 is disposed so as to be stacked. No ordinary yarn 55 is disposed between a piezoelectric yarn 1 and another piezoelectric yarn 1 adjacent to each other and between a piezoelectric yarn 2 and another piezoelectric yarn 2 adjacent to each other.

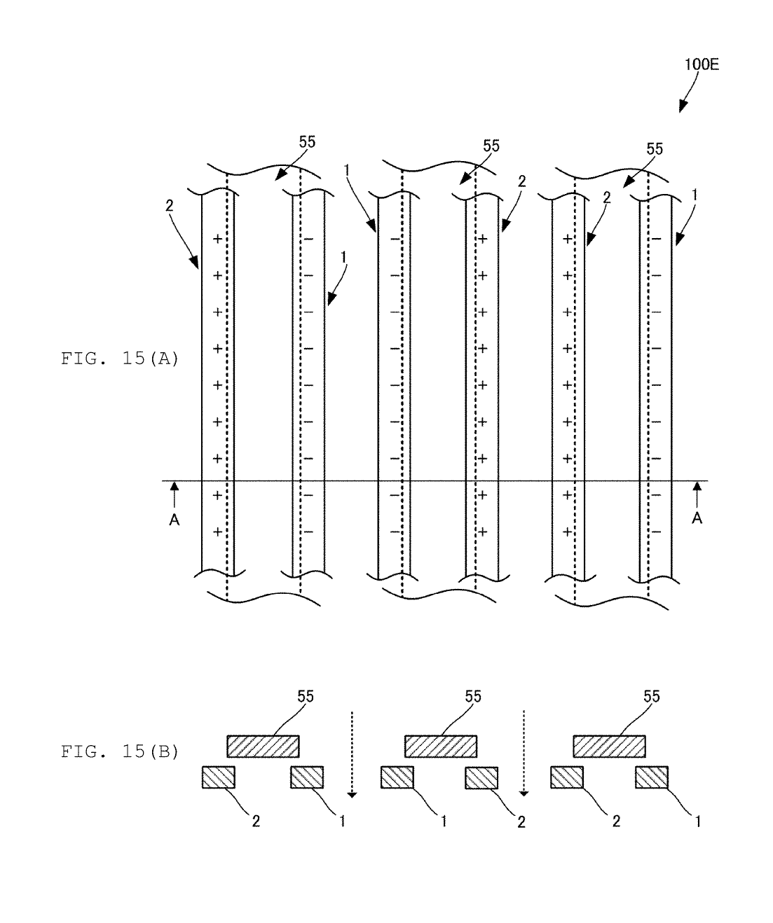

Since charges generated in the piezoelectric yarns 1 and those generated in the piezoelectric yarns 2 are different in polarity from each other as shown in FIG. 16(A) and FIG. 16(B), when external force is applied to these yarns, piezoelectric yarns 1 repel each other and a piezoelectric yarn 1 and a piezoelectric yarn 2 attract each other. Therefore, the piezoelectric yarn 1 and the piezoelectric yarn 2 overlap with the ordinary yarn 55 in plan view. Therefore, air permeability is improved. Even in such a laminated cloth 100E, the intensified the exercise, the stronger the external force on the yarns becomes, and therefore, the air permeability is improved as the exercise is intensified. On the other hand, when exercise does not occur, heat retention is secured. Therefore, also the laminated cloth 100E is configured to have improved air permeability at a time when air permeability is required such as during exercise and it is also configured to have a high heat retention at a time when heat retention is required such as out of exercise, so that the cloth is configured to have both air permeability and heat retention.

Next, FIG. 17(A) is an exploded perspective view of the laminated cloth 100F that secures heat retention, and FIG. 17(B) is a plan view thereof.

Conventionally, as a fiber that secures heat retention, there is known a configuration in which a metal powder is mixed with fibers as disclosed, for example, in Japanese Patent Application Laid-Open No. 2006-307383 and Japanese Patent Application Laid-Open No. 07-48709.

However, fibers containing metal are hard. For this reason, there is a problem that such fibers containing metal are difficult to manufacture and the texture and the comfort in wearing are deteriorated. Moreover, there can occur some metal allergic reactions.

Thus, this embodiment provides a cloth that is easy to manufacture, improves texture and comfort in wearing, and is free of the possibility of occurrence of a metal allergic reaction.

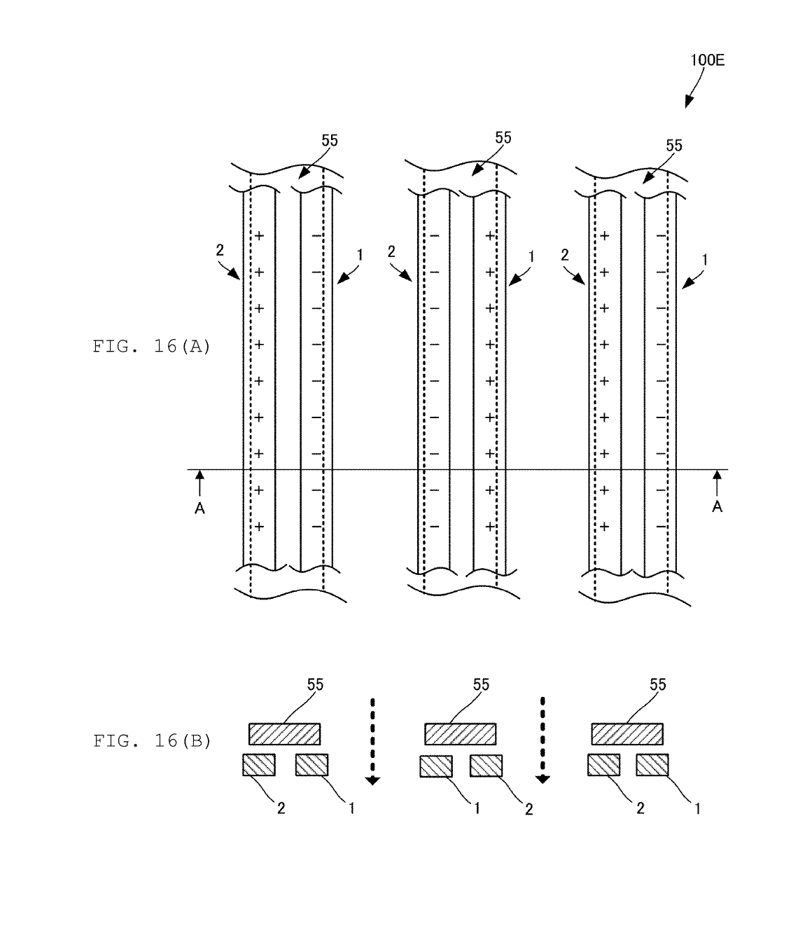

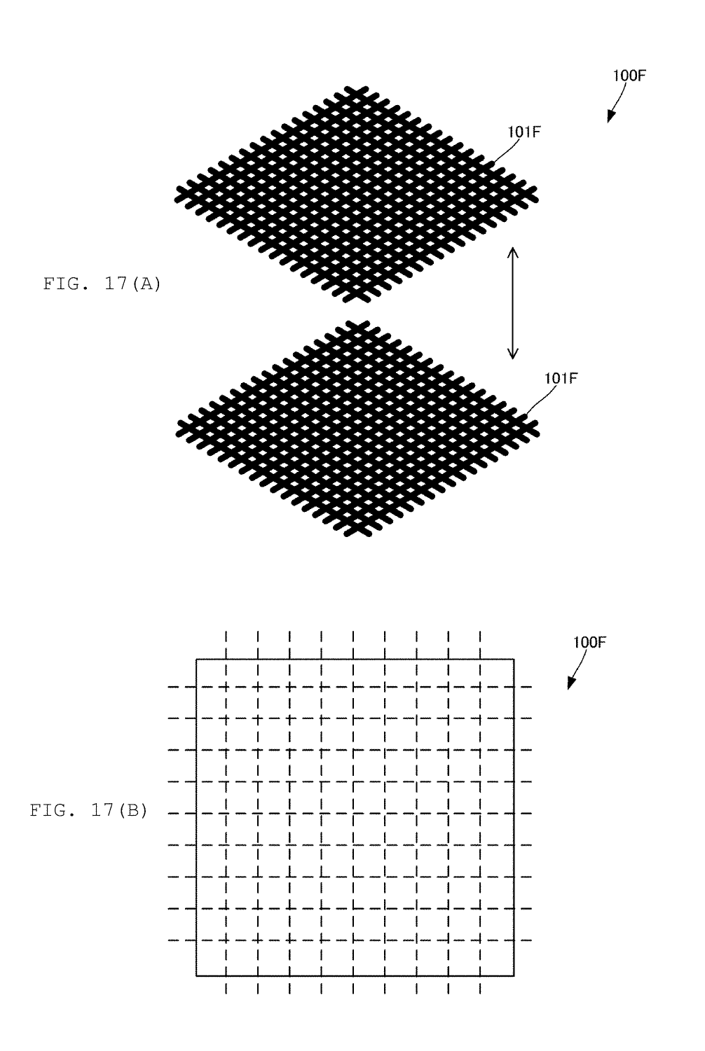

As shown in FIG. 17(A), the laminated cloth 100F is formed by laminating a plurality of cloths 101F. As shown in FIG. 17(B), each of the cloths is sewn with a yarn at prescribed intervals. As a result, in the laminated cloth 100F are formed prescribed air layers as shown in the cross-sectional view of FIG. 18(A).

The cloth 101F is made of the piezoelectric yarn 1. Accordingly, when the piezoelectric yarns 1 expand or shrink, the cloths 101F repel each other, so that the air layer becomes larger. When the air layer becomes larger, the laminated cloth 100F comes to have an enhanced heat retention effect.

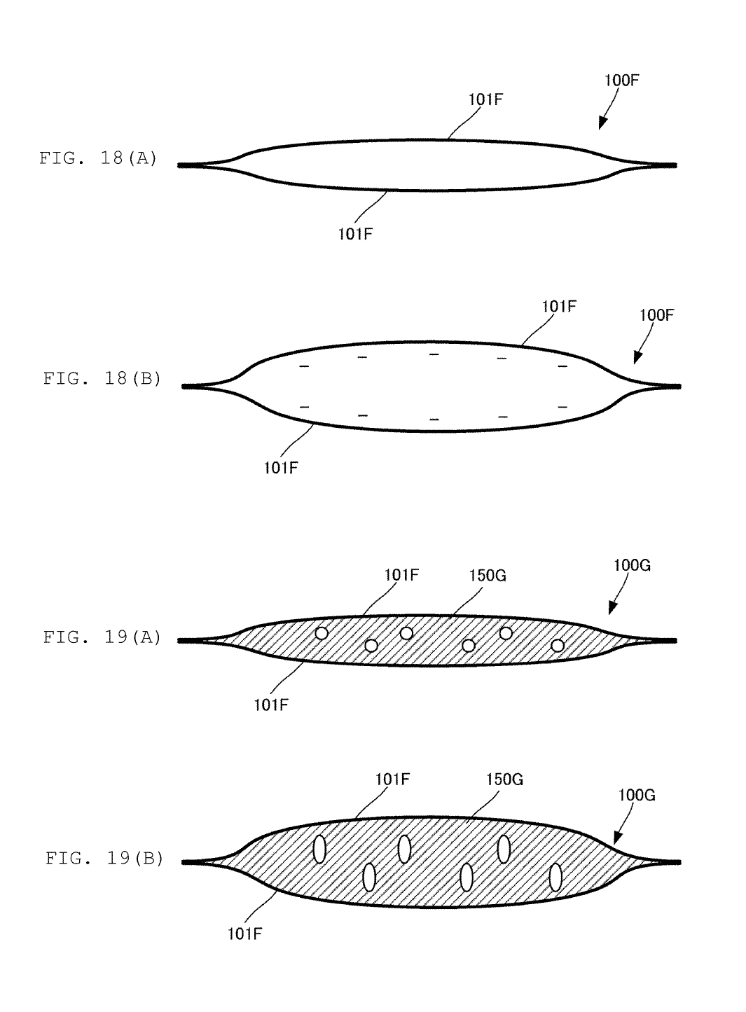

The air layer may be filled with a porous body 150G such as Cellular Teflon®, cellular polypropylene or the like, as illustrated in FIG. 19(A) and FIG. 19(B). This further improves the heat retention effect.

Although the configuration in which the piezoelectric yarns 1 that generate negative charges are allowed to repel is disclosed in the above example, it is of course possible to adopt a configuration in which the piezoelectric yarns 2 that generate positive charges are allowed to repel.

Furthermore, the piezoelectric yarns may be arranged only on a part of the cloth. Arranging the piezoelectric yarns only on a part of the cloth will cause a difference in heat retention performance depending on the location.

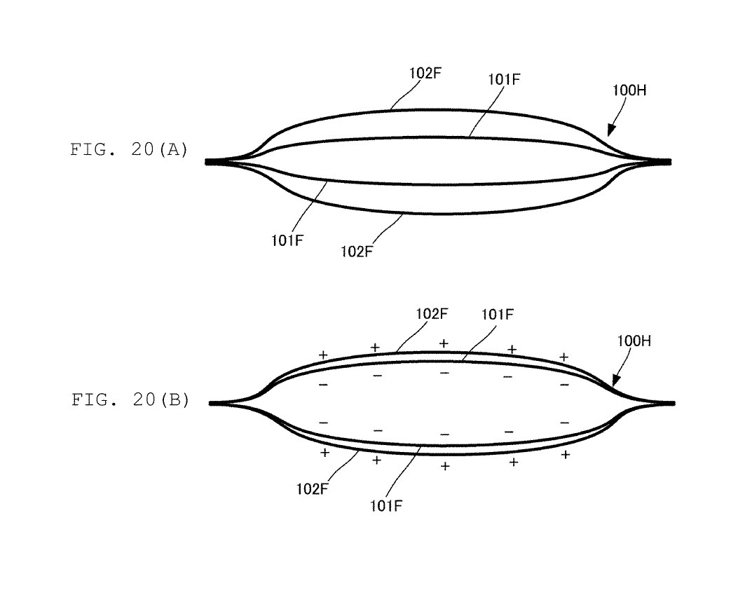

FIG. 20(A) and FIG. 20(B) are cross-sectional views showing modifications of the laminated cloth 100H. The laminated cloth 100H is formed by further laminating the cloth 102F on the outer side of the cloth 101F. The cloth 102F is made of the piezoelectric yarn 2. Therefore, when the piezoelectric yarn 1 and the piezoelectric yarn 2 expand and shrink, the cloths 101F repel each other and, concurrently, the cloth 101F and the cloth 102F attract each other, so that the air layer becomes larger. The cloth 101F to be disposed on the inner side is preferably lower in rigidity and more prone to deform than the cloth 102F disposed on the outer side.

Although the piezoelectric yarn is provided as the fiber that generates charge by external energy in the above embodiment, the fiber that generates charge by external energy may be, for example, a material having a photoelectric effect, a material having a pyroelectric effect (such as PVDF), a material that generates charges through its chemical change, or the like. Alternatively, the fiber that generates charges may have a configuration in which a conductor is used as a core yarn, an insulator is wound around the conductor, and an electricity is caused to flow through the conductor to generate charges. However, a piezoelectric body generates an electric field by piezoelectricity, and thus, no power supply is required and there is no risk of electric shock.

In addition, the lifetime of the piezoelectric body lasts longer than the antibacterial effect of a drug or the like. In addition, the piezoelectric body is less likely to cause an allergic reaction than drugs.

Finally, the description of the present embodiments is to be considered in all respects as illustrative and not restrictive. The scope of the present invention is indicated not by the above-described embodiments but by the claims. Furthermore, it is intended that the scope of the invention includes all variations within meanings and scopes equivalent to the claims.

### DESCRIPTION OF REFERENCE SYMBOLS

1, 2: Piezoelectric yarn

1A, 1C: Covering yarn

1B: Antibacterial fiber

3: Ordinary yarn

5: Conductive yarn

10: Piezoelectric film

10A: Piezoelectric fiber

11: Core yarn

55: Ordinary yarn

100, 100A, 100B, 100C, 100D, 101F, 102F: Cloth

100E, 100F, 100G, 100H: Laminated cloth

101A, 105A: Water-resistant member

110: Elastic body

150G: Porous body

900: Stretching direction

910A: First diagonal line

910B: Second diagonal line

1. An antibacterial fiber comprising:
a charge generation member shaped in a fibrous form and that generates a charge sufficient to suppress proliferation of a bacillus by input of external energy; and
a water-resistant member covering the charge generation member.

2. The antibacterial fiber according to claim 1, wherein the charge generation member includes a charge generation film having a first main surface, and the water-resistant member covers the first main surface of the charge generation film.

3. The antibacterial fiber according to claim 2, further comprising a core yarn on which the charge generation film is wound.

4. The antibacterial fiber according to claim 2, wherein the charge generation film includes a second main surface opposite the first main surface, and the water-resistant member further convers the second main surface.

5. The antibacterial fiber according to claim 1, further comprising a core yarn on which the charge generation member is wound.

6. The antibacterial fiber according to claim 5, wherein a material of the core yarn is selected from natural fibers or chemical fibers.

7. The antibacterial fiber according to claim 5, wherein the core yarn comprises polylactic acid.

8. The antibacterial fiber according to claim 5, wherein the core yarn is a conductive yarn.

8. The antibacterial fiber according to claim 1, wherein the charge generation member comprises a piezoelectric polymer.

9. The antibacterial fiber according to claim 8, wherein the piezoelectric polymer is polyvinylidene fluoride.

10. The antibacterial fiber according to claim 8, wherein the piezoelectric polymer is polylactic acid.

11. The antibacterial fiber according to claim 1, wherein, when the external energy is applied, the charge generation member generates negative charges on a surface of the fibrous form and positive charges at an inside of the fibrous form.

12. The antibacterial fiber according to claim 1, wherein, when the external energy is applied, the charge generation member generates positive charges on a surface of the fibrous form and negative charges at an inside of the fibrous form.

13. The antibacterial fiber according to claim 1, wherein
the charge generation member is made of a plurality of charge generation yarns, and
the plurality of charge generation yarns are each covered with the water-resistant member.

14. The antibacterial fiber according to claim 1, wherein the water-resistant member comprises a conductive material.

15. The antibacterial fiber according to claim 1, wherein the water-resistant member comprises an acrylic resin or a silicon-based resin.

16. The antibacterial fiber according to claim 1, wherein a charge generation member has a circular cross section and an entire periphery of the charge generation member is covered with the water-resistant member.

17. The antibacterial fiber according to claim 8, wherein the core yarn is an elastic body.

18. The antibacterial fiber according to claim 17, wherein the elastic body is made of rubber.

19. The antibacterial fiber according to claim 16, further comprising an elastic body twisted together with the charge generation member to form a covering yarn.
